(19) United States
(12) Patent Application Publication
(10) Pub. No.: US 2022/0208720 A1
(43) Pub. Date: Jun. 30, 2022

(54) SUBSTRATE BONDING APPARATUS AND SUBSTRATE BONDING METHOD

(71) Applicant: TES CO., LTD, Yongin-si (KR)

(72) Inventors: Joo-Il HA, Hwaseong-si (KR); Yeong-Been KIM, Suwon-si (KR); Jae-Hwan KIM, Hwaseong-si (KR); Dong-Min NOH, Gwangmyeong-si (KR); Woo-Pil SHIM, Yeoju-si (KR)

(73) Assignee: TES CO., LTD, Yongin-si (KR)

(21) Appl. No.: 17/556,906

(22) Filed: Dec. 20, 2021

(30) Foreign Application Priority Data
Dec. 30, 2020 (KR) 10-2020-0186902

(51) Int. Cl. H01L 23/00; H01L 23/544; H01L 21/66

(52) U.S. Cl. CPC H01L 24/75; H01L 23/544; H01L 22/20; H01L 2224/8313; H01L 2223/54426; H01L 2224/75753; H01L 24/83

(57) ABSTRACT

The present invention relates to a substrate bonding apparatus including: a chamber; a first chuck disposed inside the chamber to adhere a first substrate; a second chuck disposed facingly inside the chamber toward the first chuck to adhere a second substrate; and a camera located above or under the first chuck and the second chuck to recognize first alignment key disposed on the first substrate and second alignment key disposed on the second substrate.

### CROSS REFERENCE TO RELATED APPLICATION OF THE INVENTION

The present application claims the benefit of Korean Patent Application No. 10-2020-0186902 filed in the Korean Intellectual Property Office on Dec. 30, 2020, the entire contents of which are incorporated herein by reference.

### BACKGROUND OF THE INVENTION

### Field of the Invention

The present invention relates to a substrate bonding apparatus and method, and more specifically, to a substrate bonding apparatus and method that is capable of having a simplified configuration and reducing errors generated by misalignments of substrates, while the substrates are being bonded to each other.

### Background of the Related Art

With the development of technologies and industries, recently, high-integration for a semiconductor device or substrate (hereinafter referred to as “substrate”) has been increasingly needed. In the case where high-integrated substrates are disposed on a plane surface, connected to each other through wires, and are thus provided as a product, some problems, such as wire length increasing, wire resistance rising, and wiring delay, may occur.

Accordingly, a three-dimensional integration technology that laminates substrates three-dimensionally has been suggested. According to the three-dimensional integration technology, two substrates are bonded to each other, for example, using a bonding apparatus.

In a process of bonding the substrates, further, it is very important to align the upper substrate and the lower substrate with each other. That is, after the upper substrate and the lower substrate are aligned with each other at high precision, they are bonded to each other.

FIGS. 7A to 7C are side views showing a conventional substrate bonding method.

As shown in FIG. 7A, a conventional substrate bonding apparatus has cameras 2 and 4 disposed above and under an upper substrate 6 and a lower substrate 8, respectively, so as to align the upper substrate 6 and the lower substrate 8 with each other.

According to the conventional substrate bonding method, as shown in FIG. 7A, if the lower substrate 8 enters a space between the upper cameras 2 and the lower cameras 4, alignment key of the lower substrate 8 are recognized by the upper cameras 2.

Next, as shown in FIG. 7B, the lower substrate 8 performs an avoidance operation so that it escapes from the space between the upper cameras 2 and the lower cameras 4, and the upper substrate 6 enters the space between the upper cameras 2 and the lower cameras 4. After that, alignment key of the upper substrate 6 is recognized by the lower camera 4.

That is, if the lower substrate 8 remains in the space between the upper cameras 2 and the lower cameras 4, the alignment key of the upper substrate 6 cannot be recognized by the lower cameras 4, and accordingly, the lower substrate 8 performs the avoidance operation so that it escapes from the space between the upper cameras 2 and the lower cameras 4.

Next, as shown in FIG. 7C, the lower substrate 8 is returned to the space between the upper cameras 2 and the lower cameras 4, and the upper substrate 6 and the lower substrate 8 are aligned with each other and then bonded to each other.

However, the conventional substrate bonding method needs the avoidance operation through which the substrate whose alignment key have been recognized escapes from the space between the cameras and the returning operation through which the substrate is returned to the space between the cameras. In the processes of performing the avoidance operation and the returning operation, accordingly, errors may occur so that the substrate is not returned accurately to the coordinate values originally stored. As substrate bonding requires high precision, therefore, such coordinate errors have bad influences on the substrate bonding to undesirably increase a defect rate.

To compensate for the errors generated during the returning operation of the substrate, further, conventional technologies using compensation through a laser interferometer or separate optical meter have been developed, but in the process of bonding the substrates, such compensation methods are added, thereby increasing the time required for substrate bonding to lower efficiency in the substrate bonding.

Besides, the conventional substrate bonding apparatus has the cameras disposed on both the upper portion and the lower portions in an interior of the chamber, so that the apparatus becomes complicated in configuration, exhibits low space utilization in the chamber, and provides hard maintenance.

### SUMMARY OF THE INVENTION

Accordingly, the present invention has been made in view of the above-mentioned problems occurring in the related art, and it is an object of the present invention to provide a substrate bonding apparatus that is capable of having a simplified configuration and enhancing space utilization in a chamber thereof.

It is another object of the present invention to provide a substrate bonding method that is capable of reducing defects generated by misalignments of substrates, while the substrates are being bonded to each other.

To accomplish the above-mentioned objects, according to one aspect of the present invention, there is provided a substrate bonding apparatus including: a chamber; a first chuck configured inside the chamber to adhere a first substrate; a second chuck configured facingly inside the chamber toward the first chuck to adhere a second substrate; and a camera located above or under the first chuck and the second chuck to recognize first alignment key configured on the first substrate and second alignment key configured on the second substrate.

According to the present invention, the substrate bonding apparatus may further include a first stage disposed inside the chamber and a second stage disposed inside the chamber and movable relatively to the first stage in vertical and horizontal directions, and in this case, the first chuck and the second chuck are mounted on the first stage and the second stage, respectively.

According to the present invention, the camera directly recognizes either the first alignment key or the second alignment key and recognizes the other alignment key by penetrating the first substrate or the second substrate.

According to the present invention, the camera is an infrared camera.

According to the present invention, further, either the first chuck or the second chuck has first through hole and second through hole formed thereon to allow the first alignment key and the second alignment key to be photographed through the camera.

According to the present invention, the substrate bonding apparatus may further include pieces of compensation glass disposed in either the first through hole or the second through hole to adjust focal distances between the first substrate and the second substrate.

According to the present invention, the first through hole is formed at corresponding position to the first alignment key or the second alignment key, and the second through hole is formed so as not to overlap the first substrate or the second substrate.

According to the present invention, the camera directly recognizes either the first alignment key or the second alignment key through the second through hole and recognizes the other alignment key by penetrating first substrate or the second substrate through the first through hole.

According to the present invention, the substrate bonding apparatus may further include a plurality of measuring devices configured on either the first chuck or the second chuck to measure a distance between the first chuck and the second chuck and a plurality of horizontal level adjusting devices configured on the other chuck to keep the distance between the first chuck and the second chuck to a predetermined deviation or under.

To accomplish the above-mentioned objects, according to another aspect of the present invention, there is provided a substrate bonding method including the steps of: directly recognizing either first alignment key of a first substrate adhered to a first chuck or second alignment key of a second substrate adhered to a second chuck; recognizing the other alignment key by penetrating the first substrate or the second substrate; relatively moving the first chuck and the second chuck to each other to align the first alignment key of the first substrate and the second alignment key of the second substrate with each other; and bonding the first substrate and the second substrate to each other.

According to the present invention, between the step of directly recognizing either the first alignment key of the first substrate or the second alignment key of the second substrate and the step of recognizing the other alignment key by penetrating the first substrate or the second substrate, the first chuck or the second chuck sucking the first substrate or the second substrate with the first or second alignment key already recognized at the step of directly recognizing the first or second alignment key does not move.

According to the present invention, the steps of recognizing the first and second alignment key are carried out by recognizing the first and second alignment key by means of through hole formed on either the first chuck or the second chuck.

According to the present invention, the through hole may include first through hole formed at corresponding position to the first alignment key or the second alignment key and second through hole not overlapping the first substrate or the second substrate, the step of directly recognizing either the first alignment key of the first substrate or the second alignment key of the second substrate being carried out by recognizing the alignment key through the second through hole and the step of recognizing the other alignment key by penetrating the first substrate or the second substrate being carried out by recognizing the alignment key through the first through hole.

According to the present invention, the substrate bonding method may further include, between the step of directly recognizing either the first alignment key of the first substrate or the second alignment key of the second substrate and the step of recognizing the other alignment key by penetrating the first substrate or the second substrate, the step of relatively moving the first chuck and the second chuck to each other in a horizontal direction by a distance between the first through hole and the second through hole.

### BRIEF DESCRIPTION OF THE DRAWINGS

The above and other objects, features and advantages of the present invention will be apparent from the following detailed description of the embodiments of the invention in conjunction with the accompanying drawings, in which:

FIG. 1 is a side sectional view showing a substrate bonding apparatus according to the present invention;

FIG. 2 is a plan view showing a first substrate of the substrate bonding apparatus according to the present invention;

FIG. 3 is a perspective view showing a second chuck of the substrate bonding apparatus according to the present invention;

FIG. 4 is a flowchart showing a substrate bonding method according to the present invention;

FIGS. 5A to 6B are views showing steps of recognizing arrangement keys on substrates adhered to chucks through camera in the substrate bonding method according to the present invention; and

FIGS. 7A to 7C are side views showing a conventional substrate bonding method.

### DETAILED DESCRIPTION OF THE EMBODIMENTS

Hereinafter, an explanation of a configuration of a substrate bonding apparatus 1000 according to the present invention will be given in detail with reference to the attached drawings.

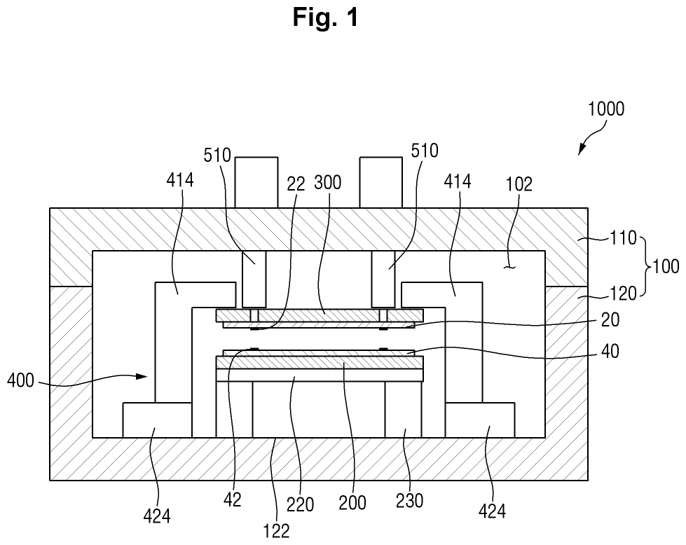

FIG. 1 is a side sectional view showing the substrate bonding apparatus 1000 according to the present invention.

Referring to FIG. 1, the substrate bonding apparatus 1000 according to the present invention includes a chamber 100, a first chuck 200 configured inside the chamber 100 to adhere a first substrate 40, a second chuck 300 configured facingly inside the chamber 100 toward the first chuck 200 and movable relatively to the first chuck 200 in vertical and horizontal directions to adhere a second substrate 20, and a camera 510 located either above or under the first chuck 200 and the second chuck 300 to recognize first alignment key 42 of the first substrate 40 and second alignment key 22 of the second substrate 20.

The chamber 100 provides a space portion 102 for accommodating the first substrate 40 and the second substrate 20 therein. For example, the chamber 100 includes a chamber body 120 and a chamber lid 110 for sealing an open top of the chamber body 120. The chamber 100 is exemplarily configured like this, but of course, the chamber 100 may be appropriately varied in configuration.

The first chuck 200 and the second chuck 300 are disposed inside the chamber 100 to fixedly adhere the first substrate 40 and the second substrate 20 thereonto. The first chuck 200 and the second chuck 3 may be vacuum chucks, electrostatic chucks, mechanical clamping chucks, and the like, and according to the present invention, vacuum chucks are used as the first chuck 200 and the second chuck 300.

The first chuck 200 is disposed in a lower space of an interior of the chamber 100 to fixedly adhere the first substrate 40 entering the interior of the chamber 100 through a robot arm (not shown) thereonto.

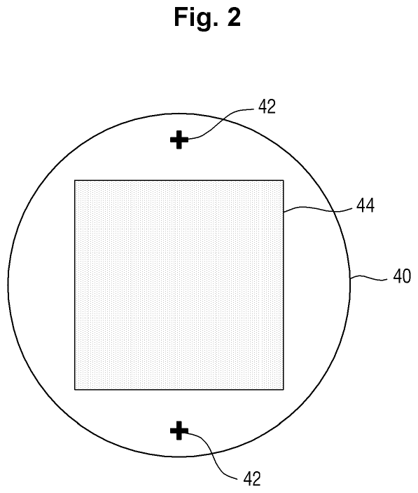

FIG. 2 is a plan view showing the first substrate 40.

Referring to FIG. 2, the first substrate 40 has a pattern 44 formed on top or a first surface thereof and the first alignment key 42 for bonding to the second substrate 20. The first alignment key 42 may be provided in plurality, and may be symmetrically disposed around a central of the first substrate 40 to provide accurate alignment of the first substrate 40. The number of first alignment key 42 and the position of the first alignment key 42 may be varied appropriately. Further, the second substrate 20 has the same configuration as the first substrate 40, and therefore, a repeated explanation will be avoided.

Referring back to FIG. 1, the first chuck 200 fixedly sticks a second surface of the first substrate 40, on which the pattern 44 is not formed, by means of a negative pressure.

Moreover, the second chuck 300 is disposed in an upper space of the interior of the chamber 100. The second chuck 300 is disposed to face the first chuck 200. That is, the second chuck 300 is disposed to face the first chuck 200 and movable relatively to the first chuck 200 in the vertical and horizontal directions. For example, both the first chuck 200 and the second chuck 300 are movable in the vertical and horizontal directions.

In a state where top and underside of the second substrate 20 become reverse to allow a first surface on which the second alignment key 22 is disposed to become the underside thereof, the second substrate 20 enters the interior of the chamber 100. The second chuck 300 fixedly sucks a second surface of the second substrate 20, on which the second alignment key 22 is not disposed, thereonto.

Further, a first stage 220 is disposed inside the chamber 100, and a second stage 400 is disposed inside the chamber 100 and movable relatively to the first stage 220 in vertical and horizontal directions.

For example, the first stage 220 is disposed on a base 122 of the chamber 100, and the first chuck 200 is disposed on the first stage 220.

Further, the second stage 400 is disposed above the first stage 220 and movable relatively to the first stage 220 in the vertical and horizontal directions. The second chuck 300 is connected to the second stage 400.

For example, the second stage 400 includes a driver 424 disposed movably on the base 122 of the chamber 100 and an extension driver 414 extended upward from the driver 424 and connected to the second chuck 300.

The driver 424 is horizontally movable on the base 122 of the chamber 100. Further, the extension driver 414 is disposed movably with respect to the driver 424 to perform precise motions.

That is, the driver 424 moves with relatively low precision, and contrarily, the extension driver 414 moves with relatively high precision to perform alignment for substrate bonding. The first stage 220 and the second stage 400 as mentioned above are exemplarily suggested, but of course, they may be varied appropriately in configuration.

Moreover, the camera 510 is disposed inside the chamber 100 to recognize the first alignment key 42 of the first substrate 40 and the second alignment key 22 of the second substrate 20. The camera 510 is located either above or under the first chuck 200 and the second chuck 300.

According to the present invention, that is, the camera 510 is not located both above and under the first chuck 200 and the second chuck 300, but they are located either above or under the first chuck 200 and the second chuck 300. Referring back to FIG. 1, the camera 510 is disposed above the first chuck 200 and the second chuck 300, and without being limited thereto, they may be disposed under the first chuck 200 and the second chuck 300. Hereinafter, an explanation will be given under the assumption that the camera 510 is disposed above the first chuck 200 and the second chuck 300.

According to the present invention, the camera 510 is disposed only either above or under the first chuck 200 and the second chuck 300, and accordingly, a configuration in an interior of the chamber 100 can be simplified, thereby enhancing space utilization of the chamber 100 and reducing a volume of the chamber 100.

Besides, the camera 510 directly recognizes either the first alignment key 42 or the second alignment key 22 and recognize the other alignment key by penetrating the first substrate 40 or the second substrate 20.

In specific, the camera 510 is disposed above the first chuck 200 and the second chuck 300, and accordingly, the camera 510 directly recognizes the first alignment key 42 of the first substrate 40 because the first alignment key 42 face them. However, the second substrate 20 has the second alignment key 22 disposed on the underside thereof, and accordingly, the camera 510 cannot directly recognize the second alignment key 22 of the second substrate 20. That is, the camera 510 recognizes the second alignment key 22 by penetrating the second substrate 20.

In the case where the first substrate 40 and the second substrate 20 are made of silicon, if an infrared (IR) camera is used as the camera 510, light emitted from the camera 510 penetrates the second substrate 20 to recognize the second alignment key 22.

The light with a wavelength longer than 0.75 μm emitted from the IR camera can be transmitted through the silicon substrate. For example, the IR camera can emit the light with a wavelength range from 1 to 2 μm, and accordingly, the light can be transmitted through the silicon substrate.

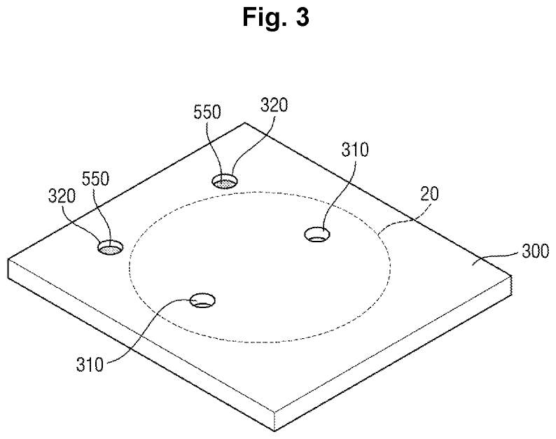

FIG. 3 is a perspective view showing the second chuck 300.

Referring to FIG. 3, the second chuck 300 has first through hole 310 and second through hole 320 adapted to allow the first alignment key 42 and the second alignment key 22 to be photographed therethrough.

Further, the first through hole 310 and the second through hole 320 may be formed on either the first chuck 200 or the second chuck 300. According to the present invention, if the camera 510 is disposed above the first chuck 200 and the second chuck 300, the first through hole 310 and the second through hole 320 is formed on the second chuck 300.

However, if the camera 510 is disposed under the first chuck 200 and the second chuck 300, the first through hole 310 and the second through hole 320 may be formed on the first chuck 200.

In specific, the first through hole 310 is formed at corresponding position to the first alignment key 42 or the second alignment key 22, and the second through hole 320 is not overlapped the first substrate 40 or the second substrate 20. Further, the camera 510 directly recognizes either the first alignment key 42 or the second alignment key 22 through the second through hole 320 and recognizes the other alignment key by penetrating the first substrate 40 or the second substrate 20 through the first through hole 310.

For example, if the second substrate 20 is fixedly adhered to the second chuck 300, the first through hole 310 is formed on the second chuck 300 at the corresponding position to the second alignment key 22 of the second substrate 20.

Further, if the second substrate 20 is fixedly adhered to the second chuck 300, the second through hole 320 is formed on the second chuck 300 in such a manner as to be not overlapped the second substrate 20.

Accordingly, the camera 510 directly recognizes the first alignment key 42 of the first substrate 40 sucked onto the first chuck 200 through the second through hole 320. Further, the camera 510 transmit the light emitted therefrom through the second substrate 20 through the first through hole 310 to recognize the second alignment key 22.

If the first substrate 40 and the second substrate 20 are bonded to each other, moreover, a high degree of precision is needed, and accordingly, high magnification camera is used as the camera 510. In this case, the camera 510 has relatively short focal distances. As the first substrate 40 and the second substrate 20 are spaced apart from each other in a vertical direction, however, it is hard for the camera 510 to recognize both the first alignment key 42 of the first substrate 40 and the second alignment key 22 of the second substrate 20. That is, if the focal distances of the camera 510 is set up to the second substrate 20, it is hard for the camera 510 to recognize the first alignment key 42 of the first substrate 40.

To solve such problems, accordingly, pieces of compensation glass 550 are disposed in either the first through hole 310 or the second through hole 320.

According to the present invention, the pieces of compensation glass 550 are disposed in the second through hole 320 to adjust the focal distances between the first substrate 40 and the second substrate 20. Further, if the pieces of compensation glass 550 are disposed in the first through hole 310, they adjust the focal distances between the first substrate 40 and the second substrate 20, and simultaneously, they adjust the refractive index of the substrate if the camera recognize the alignment key by penetrating the substrate.

Through the pieces of compensation glass 550, according to the present invention, both the first alignment key 42 of the first substrate 40 and the second alignment key 22 of the second substrate 20, which are spaced apart from each other, can be recognized by means of the single camera 510.

The pieces of compensation glass 550 are exchangeably disposed on the corresponding chuck to ensure precise focal distances according to external specification changes, such as magnification changes of the camera 510, changes in shape of the alignment key 22 and 42, changes in thickness of the substrates 20 and 40, and the like, and further, they can be adjustably disposed in position on the chuck.

Even though not shown in the drawings, further, a plurality of measuring devices may be disposed on either the first chuck 200 or the second chuck 300 to measure a distance between the first chuck 200 and the second chuck 300, and a plurality of horizontal level adjusting devices may be disposed on the other chuck to adjust the distance between the first chuck 200 and the second chuck 300 to a predetermined deviation or under.

For example, laser sensors may be used as the measuring devices and formed on either the first chuck 200 or the second chuck 300. If the distance measured by the measuring devices is greater than the predetermined deviation, the distance between the first chuck 200 and the second chuck 300 is constantly maintained by means of the horizontal level adjusting devices. For example, piezoelectric elements may be used as the horizontal level adjusting devices. In this case, the distance between the first chuck 200 and the second chuck 300 can be adjusted precisely to have a deviation within a few nm.

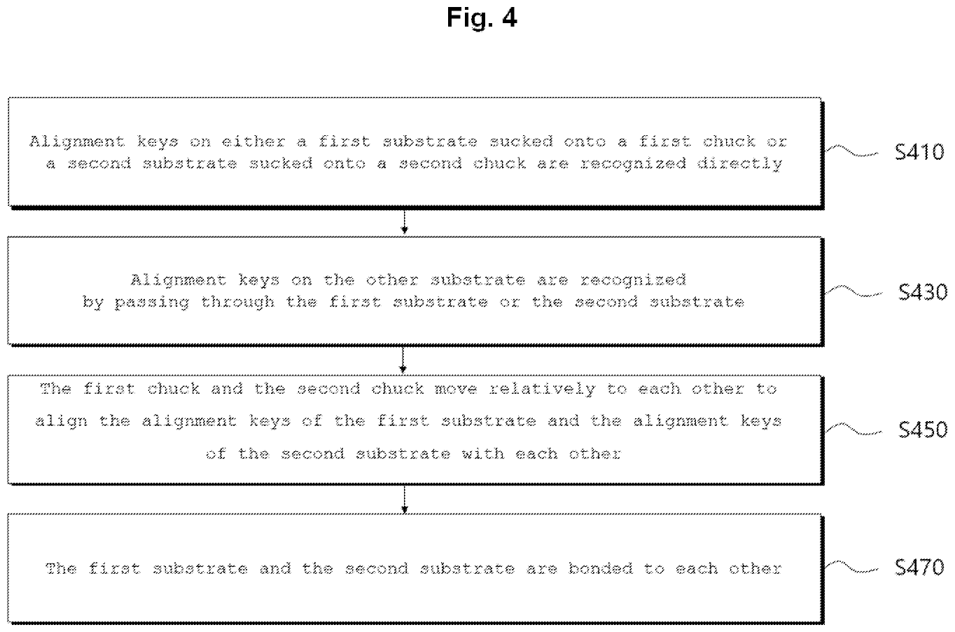

FIG. 4 is a flowchart showing a substrate bonding method according to the present invention.

Referring to FIG. 4, a substrate bonding method according to the present invention includes step S410 of directly recognizing either the first alignment key 42 of the first substrate 40 adhered to the first chuck 200 or the second alignment key 22 of the second substrate 20 adhered to the second chuck 300, step S430 of recognizing the other alignment key by penetrating the first substrate 40 or the second substrate 20, step S450 of relatively moving the first chuck 200 and the second chuck 300 to each other to align the first alignment key 42 of the first substrate 40 and the second alignment key 22 of the second substrate 20 with each other, and step S470 of bonding the first substrate 40 and the second substrate 20 to each other. Hereinafter, the substrate bonding method according to the present invention will be explained with reference to the attached drawings.

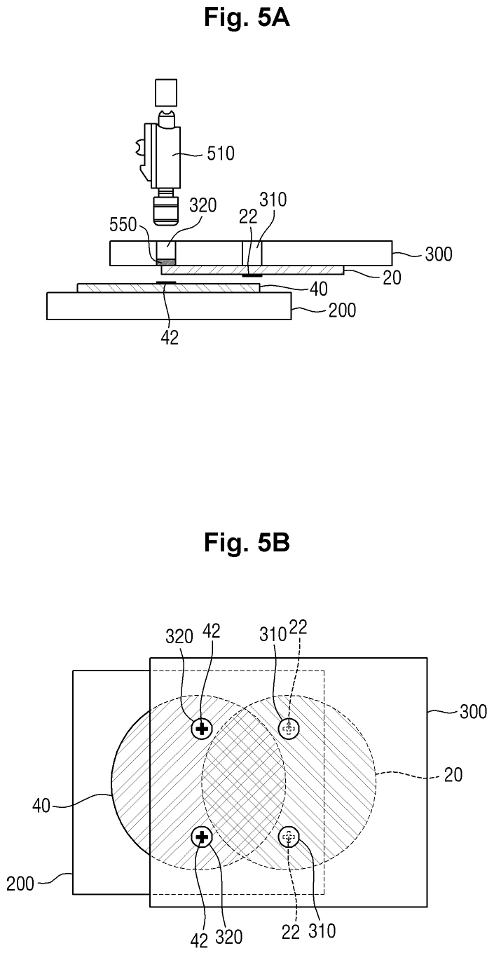

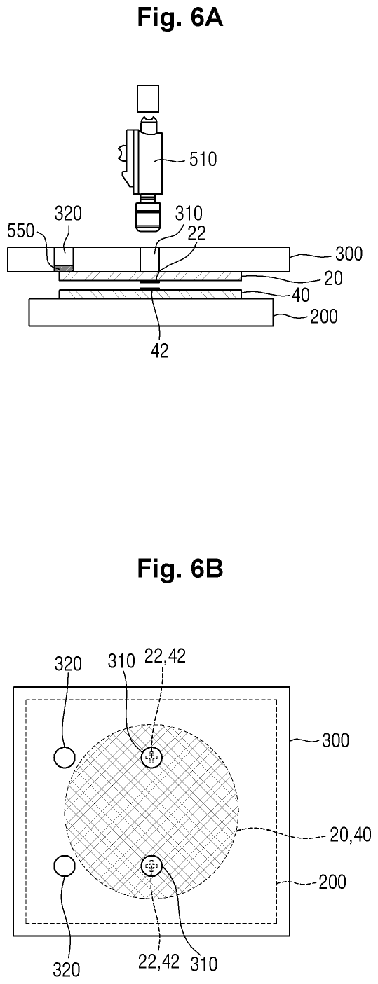

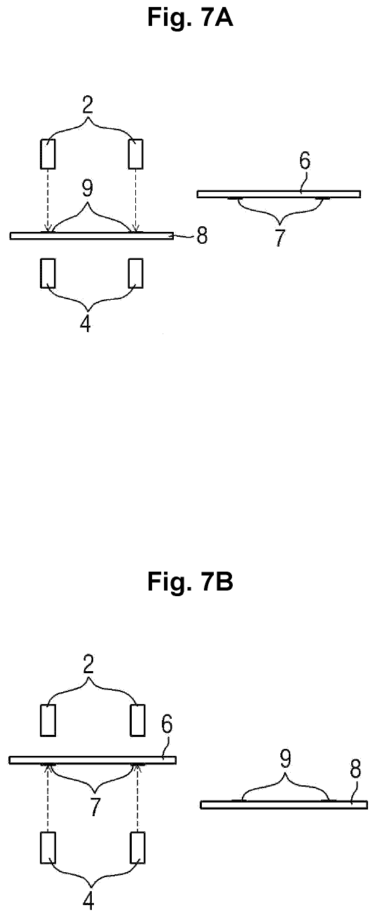

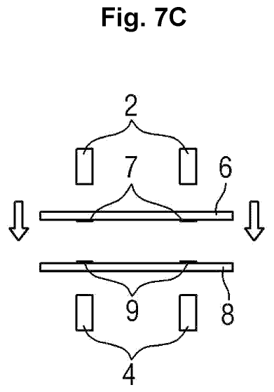

FIGS. 5A to 6B are views showing the steps of recognizing the arrangement key 22 and 42 on the first substrate 40 adhered to the first chuck 200 and the second substrate 20 adhered to the second chuck 300. FIGS. 5A and 6A are side views, and FIGS. 5B and 6B are plan views.

Referring first to FIGS. 5A and 5B, the first substrate 40 is fixedly adhered to the first chuck 200, and the second substrate 20 is fixedly adhered to the second chuck 300. Further, top and underside of the second substrate 20 become reverse so that the second substrate 20 is fixed to the second chuck 300 to face the first substrate 40 located thereunder.

Next, either the first alignment key 44 of the first substrate 40 adhered to the first chuck 200 or the second alignment key 22 of the second substrate 20 adhered to the second chuck 300 are directly recognized. Further, the steps of recognizing the alignment key 22 and 42 are carried out by recognizing the alignment key 22 and 42 through first and second through hole 310 and 320 formed on either the first chuck 200 or the second chuck 300.

Hereinafter, an explanation will be given under the assumption that the camera 510 is disposed above the first chuck 200 and the second chuck 300 and the first and second through hole 310 and 320 is formed on the second chuck 300.

For example, as shown in FIGS. 5A and 5B, the camera 510 directly recognizes the first alignment key 42 on the first substrate 40 adhered to the first chuck 200. In this case, the camera 510 directly recognizes the first alignment key 42 through the second through hole 320 of the second chuck 300.

Next, as shown in FIGS. 6A and 6B, the camera 510 recognizes the second alignment key 22 on the second substrate 20 by penetrating the second substrate 20. As mentioned above, the camera 510 is an IR camera and transmit the light with relatively long wavelengths through the silicon substrate to recognize the alignment key.

For example, the step of relatively moving the first chuck 200 and the second chuck 300 to each other in a horizontal direction by a distance between the first through hole 310 and the second through hole 320 is carried out between the step of directly recognizing either the first alignment key 44 of the first substrate 40 or the second alignment key 22 of the second substrate 20 and the step of recognizing the other alignment key by penetrating the first substrate 40 or the second substrate 20.

That is, as shown in FIGS. 6A and 6B, the second chuck 300 horizontally moves from the state as shown in FIGS. 5A and 5B.

In this case, the horizontally moving distance of the second chuck 300 corresponds to the distance between the first through hole 310 and the second through hole 320. After the second chuck 300 moves, accordingly, the first through hole 310 is located under the camera 510 in vertical directions with respect to the camera 510.

Even though not shown, after the second chuck 300 moves horizontally, a step of moving down the second chuck 300 toward the first chuck 200 in a vertical direction is further carried out.

In a state where the first chuck 200 and the second chuck 300 are arranged closest to each other to the maximum, if the alignment is carried out, the moving distances of the substrates in a vertical direction can become short at the step of bonding the substrates as will be discussed later, thereby minimizing substrate misalignment occurring when the substrates move vertically.

Further, as shown in FIGS. 6A and 6B, the camera 510 transmits the light through the second substrate 20 through the first through hole 310 to recognize the second alignment key 22.

In this case, between the step S410 of directly recognizing either the first alignment key 44 of the first substrate 40 or the second alignment key 22 of the second substrate 20 and the step S430 of recognizing the other alignment key by penetrating the first substrate 40 or the second substrate 20, the first chuck 200 sucking the first substrate 40 with the first alignment key 42 recognized at the step S410 does not move.

For example, in the case where the second chuck 300 horizontally moves by the distance between the first through hole 310 and the second through hole 320, the first chuck 200 does not move.

According to the present invention, so as to recognize the second alignment key 22 of the second substrate 20 after the first alignment key 42 of the first substrate 40 has been recognized, accordingly, there is no need to move the first substrate 40, so that errors or misalignment occurring when the first substrate 40 is returned to the second substrate 20 can be minimized.

If the first alignment key 42 and the second alignment key 22 are recognized by the camera 510, further, their coordinates can be calculated through a controller (not shown) of the substrate bonding apparatus 1000. After the coordinates of the first alignment key 42 and the second alignment key 22 are calculated, the first chuck 200 and the second chuck 300 move relatively to each other to align the first alignment key 42 of the first substrate 40 and the second alignment key 22 of the second substrate 20 with each other, and next, the second chuck 300 moves down to allow the first substrate 40 and the second substrate 20 to be bonded to each other.

As described above, the substrate bonding apparatus according to the present invention is configured to allow the camera to be disposed either above or under the first chuck and the second chuck, so that the substrate bonding apparatus can be more simplified in configuration than the conventional technologies and enhance the space utilization in the chamber.

In addition, the substrate bonding method according to the present invention is carried out to have no avoidance and returning operations of the substrate, so that the coordinate errors can be prevented from occurring due to the returning operation of the substrate to thus reduce the defects caused by the misalignment of the substrates.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A substrate bonding apparatus comprising:
a chamber;
a first chuck configured inside the chamber to adhere a first substrate;
a second chuck configured facingly inside the chamber toward the first chuck to adhere a second substrate; and
a camera located either above or under the first chuck and the second chuck to recognize first alignment key configured on the first substrate and second alignment key configured on the second substrate.

2. The substrate bonding apparatus according to claim 1, further comprising:
a first stage disposed inside the chamber; and
a second stage disposed inside the chamber and movable relatively to the first stage in vertical and horizontal directions,
wherein the first chuck and the second chuck being mounted on the first stage and the second stage, respectively.

3. The substrate bonding apparatus according to claim 1, wherein the camera directly recognizes either the first alignment key or the second alignment key and recognizes the other alignment key by passing through the first substrate or the second substrate.

4. The substrate bonding apparatus according to claim 3, wherein the camera is an infrared camera.

5. The substrate bonding apparatus according to claim 1, wherein either the first chuck or the second chuck has first through hole and second through hole formed thereon to allow the first alignment key and the second alignment key to be photographed through the camera.

6. The substrate bonding apparatus according to claim 5, further comprising compensation glass disposed in either the first through hole or the second through hole to adjust focal distances between the first substrate and the second substrate.

7. The substrate bonding apparatus according to claim 5, wherein the first through hole is formed at corresponding position to the first alignment key or the second alignment key, and the second through hole is formed so as not to overlap the first substrate or the second substrate.

8. The substrate bonding apparatus according to claim 7, wherein the camera directly recognizes either the first alignment key or the second alignment key through the second through hole and recognizes the other alignment key by penetrating the first substrate or the second substrate through the first through hole.

9. The substrate bonding apparatus according to claim 1, further comprising a plurality of measuring devices configured on either the first chuck or the second chuck to measure a distance between the first chuck and the second chuck, and a plurality of horizontal level adjusting devices disposed on the other chuck to keep the distance between the first chuck and the second chuck to a predetermined deviation or under.

10. A substrate bonding method comprising the steps of:
directly recognizing either first alignment key of a first substrate adhered to a first chuck or second alignment key of a second substrate adhered to a second chuck;
recognizing the other alignment key by penetrating the first substrate or the second substrate;
relatively moving the first chuck and the second chuck to each other to align the first alignment key of the first substrate and the second alignment key of the second substrate with each other; and
bonding the first substrate and the second substrate to each other.

11. The substrate bonding method according to claim 10, wherein between the step of directly recognizing either the first alignment key of the first substrate or the second alignment key of the second substrate and the step of recognizing the other alignment key by penetrating the first substrate or the second substrate,
the first chuck or the second chuck adhered to the first substrate or the second substrate with the first or second alignment key already recognized at the step of directly recognizing the first or second alignment key does not move.

12. The substrate bonding method according to claim 10, wherein the steps of recognizing the first and second alignment key are carried out by recognizing the first and second alignment key by means of through hole formed on either the first chuck or the second chuck.

13. The substrate bonding method according to claim 12, wherein the through hole comprises first through hole formed at corresponding position to the first alignment key or the second alignment key and second through hole not overlapping the first substrate or the second substrate,
the step of directly recognizing either the first alignment key of the first substrate or the second alignment key of the second substrate being carried out by recognizing the alignment key through the second through hole and the step of recognizing the other alignment key by penetrating the first substrate or the second substrate being carried out by recognizing the alignment key through the first through hole.

14. The substrate bonding method according to claim 13, further comprising, between the step of directly recognizing either the first alignment key of the first substrate or the second alignment key of the second substrate and the step of recognizing the other alignment key by penetrating the first substrate or the second substrate, the step of relatively moving the first chuck and the second chuck to each other in a horizontal direction by a distance between the first through hole and the second through hole.
